(19) United States
(12) Patent Application Publication
(10) Pub. No.: US 2024/0014226 A1
(43) Pub. Date: Jan. 11, 2024

(54) ARRAY SUBSTRATE AND MANUFACTURING METHOD THEREOF

(71) Applicant: Shenzhen China Star Optoelectronics Semiconductor Display Technology Co., Ltd., Shenzhen (CN)

(72) Inventors: Jingyuan HU, Shenzhen (CN); Fanjing WU, Shenzhen (CN)

(73) Assignee: Shenzhen China Star Optoelectronics Semiconductor Display Technology Co., Ltd., Shenzhen (CN)

(21) Appl. No.: 17/874,457

(22) Filed: Jul. 27, 2022

(30) Foreign Application Priority Data
Jul. 7, 2022 (CN) 202210803581.7

(51) Int. Cl. H01L 27/12

(52) U.S. Cl. CPC H01L 27/1251; H01L 27/1222; H01L 27/127

(57) ABSTRACT

The embodiment of the present invention discloses an array substrate and a manufacturing method thereof. The array substrate includes a substrate layer, and a thin-film transistor structure layer disposed on the substrate layer. The substrate layer includes a first substrate layer; a first barrier layer disposed on the first substrate layer; a metal layer disposed on the first barrier layer, and the metal layer includes a plurality of light-shading blocks arranged at intervals; and a second substrate layer disposed on the metal layer and covering the plurality of light-shading blocks arranged at intervals.

### BACKGROUND

### Field of Invention

The present invention relates to a field of display panels, in particular, to an array substrate and a manufacturing method thereof.

### Description of Prior Art

In recent years, flexible folding technology has attracted much attention, but the flexible folding technology also puts forward higher requirements for a bending property of flexible substrates.

Please refer to FIG. 1, FIG. 1 is a schematic structural diagram of an array substrate in a flexible display panel in a prior art. The array substrate comprises a substrate layer 10 and a thin-film transistor structure layer 20. The substrate layer 10 comprises a base 110, a first isolation layer 120, a first substrate layer 130, a first barrier layer 140, a second isolation layer 122, a second substrate layer 160, and a second barrier layer 170. The thin-film transistor structure layer 20 comprises a buffer layer 210, a light-shading layer 180, an active layer 220, a gate insulating layer 230, a gate electrode layer 240, an interlayer dielectric layer 250, contact holes 251, buffer holes 190, a source/drain electrode layer 260, a passivation layer 270, a wiring layer 280, a planarization layer 290, a pixel electrode layer 310, and a pixel definition layer 320. The source/drain electrode 260 is connected to the light-shading layer 180 through the buffer holes 190.

Facing increasingly complex product designs and performance requirements, conventional designs for the array substrate cannot effectively disperse bending stress, and it is difficult to meet requirements of the flexible substrates; In addition, a manufacturing process of the array substrate is complex, which is a reason for its high price. Finding ways to save cost of the manufacturing process is particularly important in a competitive panel industry.

### SUMMARY

The embodiments of the present invention provide an array substrate and a manufacturing method thereof, so as to solve problems that an array substrate in the prior art cannot effectively disperse bending stress, and high cost caused by a complex manufacturing process of the array substrate.

In order to solve the above technical problems, the embodiments of the present invention disclose following technical solutions:

On the one hand, providing an array substrate, comprising a substrate layer and a thin-film transistor structure layer disposed on the substrate layer; the substrate layer comprising:
a first substrate layer;
a first barrier layer disposed on the first substrate layer;
a metal layer disposed on the first barrier layer, and the metal layer comprising a plurality of light-shading blocks arranged at intervals; and
a second substrate layer disposed on the metal layer and covering the plurality of light-shading blocks arranged at intervals.

In addition to or as an alternative to one or more of the features disclosed above, parts of the second substrate layer located between the light-shading blocks form a plurality of bumps facing the first substrate layer.

In addition to or as an alternative to one or more of the features disclosed above, the thin-film transistor structure layer comprises a plurality of thin-film transistor devices, the light-shading blocks are arranged corresponding to the thin-film transistor devices one by one, and projections of the thin-film transistor devices on the first substrate fall within projections of the light-shading blocks on the first substrate layer.

In addition to or as an alternative to one or more of the features disclosed above, a sectional shape of each of the light-shading blocks is a square, a trapezoid, or a cone.

In addition to or as an alternative to one or more of the features disclosed above, a material of the light-shading blocks comprises titanium alloy, titanium molybdenum alloy, or ferroalloy, and a thickness of the light-shading blocks is greater than 0 angstrom and less than 3000 angstroms.

In addition to or as an alternative to one or more of the features disclosed above, the first barrier layer is an inorganic insulating layer, the plurality of light-shading blocks arranged at intervals are disposed on the inorganic insulating layer, and the plurality of bumps are in contact with the inorganic insulating layer.

In addition to or as an alternative to one or more of the features disclosed above, the substrate layer further comprises:
a base; and
a first isolation layer disposed on the base;
wherein the first substrate layer is disposed on the first isolation layer.

In addition to or as an alternative to one or more of the features disclosed above, the substrate layer further comprises a second barrier layer arranged on the second substrate layer; wherein the second barrier layer comprises:
a first silicon oxide layer disposed on the second substrate layer;
a silicon nitride layer disposed on the first silicon oxide layer;
a second silicon oxide layer disposed on the silicon nitride layer;
wherein the thin-film transistor structure layer is disposed on the second silicon oxide layer.

In addition to or as an alternative to one or more of the features disclosed above, the thin-film transistor structure layer comprises:
an active layer disposed on the substrate layer;
a gate insulating layer disposed on the active layer;
a gate electrode layer disposed on the gate insulating layer;
an interlayer dielectric layer disposed on the gate electrode layer; wherein the interlayer dielectric layer is defined with contact holes, the contact holes extend from a side of the interlayer dielectric layer away from the substrate layer to a surface of the active layer away from the substrate layer;
a source/drain electrode layer disposed on the interlayer dielectric layer, wherein the source/drain electrode layer is connected to the active layer through the contact holes to form the thin-film transistor devices.

On the other hand, providing a manufacturing method for preparing the array substrate according to the present invention. The manufacturing method comprises following steps: preparing the substrate layer; preparing the thin-film transistor structure layer on the substrate layer; a step of preparing the substrate layer comprises following steps: preparing the first substrate layer; preparing the first barrier layer on the first substrate layer; preparing the metal layer on the first barrier layer, patterning the metal layer to form a plurality of light-shading blocks arranged at intervals; preparing the second substrate layer on the metal layer, and the second substrate layer covering the plurality of light-shading blocks arranged at intervals.

The present invention further provides an array substrate, comprising a substrate layer and a thin-film transistor structure layer disposed on the substrate layer; the substrate layer comprising:
a first substrate layer;
a first barrier layer disposed on the first substrate layer;
a metal layer disposed on the first barrier layer, the metal layer comprising a plurality of light-shading blocks arranged at intervals, and a thickness of the light-shading blocks being less than 3000 angstroms
a second substrate layer disposed on the metal layer and covering the plurality of light-shading blocks arranged at intervals, and parts of the second substrate layer located between the light-shading blocks forming a plurality of bumps facing the first substrate layer.

One of the above technical solutions has following advantages or beneficial effects: the present application can play a light-shading effect by disposing a metal layer on a first barrier layer and patterning the metal layer into light-shading blocks; at a same time, the light-shading blocks arranged at intervals can improve a surface roughness, increase an adhesion of the first barrier layer to a second substrate layer, and prevent the second substrate layer from falling off or cracking. A plurality of bumps formed by the downward projection of the second substrate layer can disperse bending stress and improve flexibility of the array substrate.

Moreover, the light-shading blocks can replace a light-shading layer in the prior art, so steps of preparing the light-shading layer can be canceled, and cost of the light-shading layer can be saved. In addition, there is no need to prepare buffer holes, which saves a mask for preparing the buffer holes and further saves the cost.

### BRIEF DESCRIPTION OF DRAWINGS

Technical schemes and other beneficial effects of the present invention will be apparent through detailed description of the specific embodiments of the present invention in combination with accompanying drawings.

FIG. 1 is a schematic structural diagram of an array substrate in prior art.

FIG. 2 is a schematic structural diagram of an array substrate provided by embodiments of the present invention.

FIG. 3 is a flowchart of a manufacturing method of the array substrate provided by embodiments of the present invention.

FIG. 4 is a schematic structural diagram of step 14 of the manufacturing method of the array substrate provided by the embodiments of the present invention.

FIG. 5 is a schematic structural diagram of step 15 of the manufacturing method of the array substrate provided by the embodiments of the present invention.

FIG. 6 is a schematic structural diagram of step 16 of the manufacturing method of the array substrate provided by the embodiments of the present invention.

FIG. 7 is a schematic structural diagram of step 17 of the manufacturing method of the array substrate provided by the embodiments of the present invention.

FIG. 8 is a schematic structural diagram of step 21 of the manufacturing method of the array substrate provided by the embodiments of the present invention.

FIG. 9 is a schematic structural diagram of step 22 of the manufacturing method of the array substrate provided by the embodiments of the present invention.

FIG. 10 is a schematic structural diagram of step 23 of the manufacturing method of the array substrate provided by the embodiments of the present invention.

FIG. 11 is a schematic structural diagram of step 24 of the manufacturing method of the array substrate provided by the embodiments of the present invention.

### REFERENCE MARKS

array substrate—100; substrate layer—10;
thin-film transistor structure layer—20; base—110;
first isolation layer—120; first substrate layer—130;
first barrier layer—140; metal layer—150;
light-shading blocks—151; second substrate layer—160;
second barrier layer—170; first silicon oxide layer—171;
silicon nitride layer—172; second silicon oxide layer—173;
buffer layer—210; active layer—220;
gate insulating layer—230; gate electrode layer—240;
interlayer dielectric layer—250; source/drain electrode layer—260;
contact holes—251; wiring layer—270;
passivation layer—280; planarization layer—290;
pixel electrode layer—310; pixel definition layer—320;
light-shading layer—180; buffer holes—190;
second isolation layer—122.

### DETAILED DESCRIPTION OF PREFERRED EMBODIMENTS

In the following, the technical scheme in the embodiments of the present invention will be described clearly and completely in combination with the drawings. In the description of the present invention, it should be understood that the orientation or positional relationship indicated by the terms “center”, “longitudinal”, “transverse”, “length”, “width”, “thickness”, “up”, “down”, “front”, “back”, “left”, “right”, “vertical”, “horizontal”, “top”, “bottom”, “inner”, “outer”, “clockwise needle”, “counterclockwise” is based on an orientation or a positional relationship shown in the attached drawings, only for the convenience of describing the present application and simplifying the description, rather than indicating or implying that the device or element referred to must have a specific orientation constructed and operated in a specific orientation, therefore, it cannot be understood as a restriction on the present application.

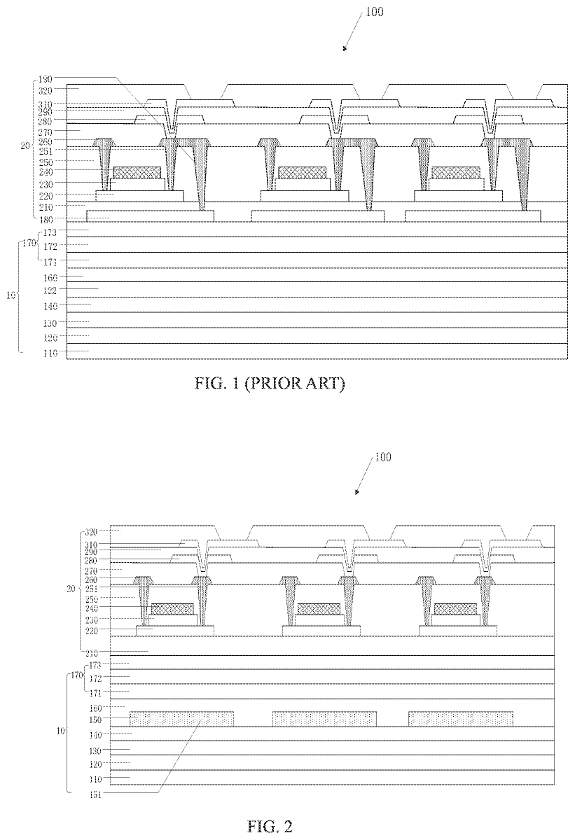

Please refer to FIG. 2. FIG. 2 is a schematic structural diagram of an array substrate 100 provided by embodiments of the present invention. The array substrate 100 comprises a substrate layer 10 and a thin-film transistor structure layer 20.

The substrate layer 10 comprises a base 110, a first isolation layer 120, a first substrate layer 130, a first barrier layer 140, a metal layer 150, a second substrate layer 160, and a second barrier layer 170.

The base 110 is a base member for carrying an array structure. A manufacturing process of the array substrate 100 is to use the base 10 as a support, and then peel a substrate film from the base 10. In the embodiment, the base 10 can be made of glass.

The first isolation layer 120 is disposed on the base 110, and the first isolation layer 120 can be made of α-Si. On the one hand, the first isolation layer 120 can improve surface roughness, which is conducive to attachment of the first substrate layer 130. On the other hand, laser stripping technology can be used to make α-Si gasify and facilitates a separation of the first substrate layer 130 from the base 110.

The first substrate layer 130 is disposed on the first isolation layer 120, and the first substrate layer 130 can be made of an organic material. The organic material can be any one or more combinations of polyimide, polyethylene, polypropylene, polystyrene, polyethylene terephthalate, and polyethylene naphthalate.

The first barrier layer 140 is disposed on the first substrate layer 130. The

first barrier layer 140 can be made of inorganic materials. For example, the inorganic materials can be one or more combinations of alumina, silicon oxide, silicon nitride, silicon oxynitride, silicon carbide, titanium oxide, zirconia, and zinc oxide. A thickness of the first barrier layer 140 ranges from 5 microns to 10 microns. The first barrier layer 140 can be used to block water and oxygen and prevent failure of thin-film transistor devices in the array substrate 100.

The metal layer 150 is disposed on the first barrier layer 140, and the metal layer 150 comprises a plurality of light-shading blocks 151 arranged at intervals. The first barrier layer 140 is an inorganic insulating layer, and the plurality of light-shading blocks 151 arranged at intervals are disposed on the inorganic insulating layer. By disposing the metal layer 150 on the first barrier layer 140 and patterning the metal layer 150 into the light-shading blocks 151, a light-shading effect can be achieved. Moreover, when a bending force is applied, stress is mainly applied between the light-shading blocks 151, which can effectively reduce damage of bending to the thin-film transistor devices and light-emitting devices on the array substrate and improve product performance.

A sectional shape of each of the light-shading blocks 151 can be a square, a trapezoid, or a cone. Different shapes can be adjusted according to a process accuracy. Spacing between the light-shading blocks 151 can also be different, which is not limited by the embodiments of the present application. The light-shading blocks 151 are made of titanium alloy, titanium molybdenum alloy, or ferroalloy. A thickness of the light-shading blocks 151 is less than 3000 angstroms.

The second substrate layer 160 is disposed on the metal layer 150 and covers the light-shading blocks 151. Parts of the second substrate layer 160 located between the light-shading blocks 151 form a plurality of bumps facing the first substrate layer 130, and the bumps are in contact with the inorganic insulating layer. The light-shading blocks 151 arranged at intervals can improve the surface roughness, increase an adhesion of the first barrier layer 140 to the second substrate layer 160, and prevent the second substrate layer 160 from peeling off or cracking. The plurality of bumps formed by a downward projection of the second substrate layer 160 can disperse bending stress and improve flexibility of the array substrate.

The second substrate layer 160 can be made of an organic material. The organic material can be any one or more combinations of polyimide, polyethylene, polypropylene, polystyrene, polyethylene terephthalate, and polyethylene naphthalate. A reason of manufacturing the first substrate layer 130 and the second substrate layer 160 is that two organic layers can be used as a substrate to improve yield. In addition, there are many impurities such as particles and dust on one layer of organic substrate. Making two layers of organic substrates can reduce problems of particles, dust, and other impurities.

In other embodiments, an inorganic insulating layer (not shown in the figures) can also be arranged between the first substrate layer 130 and the second substrate layer 160, in which the plurality of light-shading blocks 151 arranged at intervals are disposed on the inorganic insulating layer, and the plurality of bumps are in contact with the inorganic insulating layer.

The second barrier layer 170 is disposed on the second substrate layer 160, and the second barrier layer 170 comprises a first silicon oxide layer 171, a silicon nitride layer 172, and a second silicon oxide layer 173. The first silicon oxide layer 171 is disposed on the second substrate layer 160. The silicon nitride layer 172 is disposed on the first silicon oxide layer 171. The second silicon oxide layer 173 is disposed on the silicon nitride layer 172.

The thin-film transistor structure layer 20 comprises a buffer layer 210, an active layer 220, a gate insulating layer 230, a gate electrode layer 240, an interlayer dielectric layer 250, a source/drain electrode layer 260, a wiring layer 280, a pas sivation layer 270, a planarization layer 290, contact holes 251, a pixel electrode layer 310, and a pixel definition layer 320.

The buffer layer 210 is disposed on the substrate layer 10. The buffer layer 210 is used to block water and oxygen on the light-shading layer 180. In the embodiment, the second barrier layer 170 has been made of a material that blocks water and oxygen, so the buffer layer 210 can be omitted, thereby saving costs, and simplifying the manufacturing process.

The active layer 220 is disposed on the buffer layer 210. The gate insulating layer 230 is arranged on the active layer 220. The gate insulating layer 230 comprises an inorganic layer such as silicon oxide and silicon nitride, and the gate insulating layer 230 can comprise a single layer or a plurality of layers. The gate electrode layer 240 is disposed on the gate insulating layer 230. The interlayer dielectric layer 250 is disposed on the gate electrode layer 240, and the interlayer dielectric layer 250 can comprise inorganic materials or organic materials. The inorganic materials can comprise at least one selected from silicon nitride, aluminum nitride, zirconium nitride, titanium nitride, hafnium nitride, tantalum nitride, silicon oxide, aluminum oxide, titanium oxide, tin oxide, cerium oxide, and silicon oxynitride. The organic materials can comprise at least one selected from acrylic resin, methacrylic resin, polyisoprene, vinyl resin, epoxy resin, urethane resin, cellulose resin, and perylene resin.

The source/drain electrode layer 260 is disposed on the interlayer dielectric layer 250, and a material of the source/drain electrode layer 260 can be any one or more of silver, molybdenum, aluminum, and copper. The contact holes 251 extends from a side of the interlayer dielectric layer 250 away from the substrate layer 10 to a surface of the active layer 220 away from the substrate layer 10, and the source/drain electrode layer 260 is connected to the active layer 220 through the contact holes 251 to form the thin-film transistor devices. The light-shading blocks 151 are arranged corresponding to the thin-film transistor devices, and projections of the thin-film transistor devices on the first substrate layer 130 fall within projections of the light-shading block 151 on the first substrate layer 130. The light-shading blocks 151 are used to shield the thin-film transistor devices from ambient light from a bottom of the array substrate.

The passivation layer 270 is disposed on the source/drain electrode layer 260; the wiring layer 280 is disposed on the passivation layer 270; and the planarization layer 290 is disposed on the wiring layer 280. The planarization layer 290 can comprise organic materials such as acrylic, polyimide (PI), or benzocyclobutene (BCB), and the planarization layer 290 has a planarizing effect.

The pixel electrode layer 310 is disposed on the planarization layer 290, and the pixel definition layer 320 is disposed on the pixel electrode layer 310. The setting of the pixel electrode layer 310 and the pixel definition layer 320 is a technical means well known to those skilled in the art and will not be repeated here.

The embodiments of the present invention further provides a manufacturing method of an array substrate 100 involved in the present invention. Please refer to FIG. 3, FIG. 3 is a flowchart of the manufacturing method of the array substrate 100, and the manufacturing method comprises steps 1-2.

Step 1: preparing a substrate layer 10.

Specifically, step 1 comprises steps 11 to 17:

Step 11: providing a base 110.

The base 110 is a base member for carrying an array structure. A manufacturing process of the array substrate 100 is to use the base 110 as a support, and then peel a substrate film from the base 110. In the embodiment, the base 110 can be made of glass.

Step 12: preparing a first isolation layer 120 on the base 110.

The first isolation layer 120 can adopt α-Si, on the one hand, the first isolation layer 120 can improve surface roughness, which is conducive to an attachment of the first substrate layer 130. On the other hand, laser stripping technology can be used to make α-Si gasify and facilitates a separation of the first substrate layer 130 from the base 110.

Step 13: preparing a first substrate layer 130 on the first isolation layer 120.

The first substrate layer 130 can be made of an organic material. The organic material can be any one or more combinations of polyimide, polyethylene, polypropylene, polystyrene, polyethylene terephthalate, and polyethylene naphthalate.

Step 14: preparing a first barrier layer 140 on the first substrate layer 130.

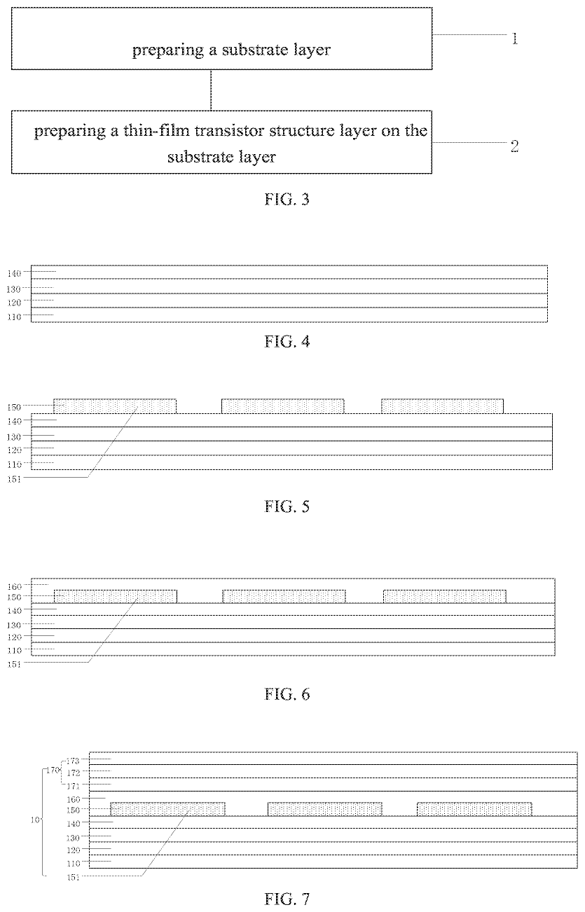

Please refer to FIG. 4, FIG. 4 is a schematic structural diagram of step 14 of the manufacturing method.

Specifically, the first barrier layer 140 is deposited on the first substrate layer 130. A thickness of the first barrier layer 140 ranges from 5 microns to 10 microns. The first barrier layer 140 can be made of inorganic materials. For example, the inorganic materials can be one or more combinations of alumina, silicon oxide, silicon nitride, silicon oxynitride, silicon carbide, titanium oxide, zirconia, and zinc oxide. The first barrier layer 140 can be used to block water and oxygen and prevent failure of thin-film transistor devices in the array substrate 100.

Step 15: preparing a metal layer 150 on the first barrier layer 140 and patterning the metal layer 150 to form a plurality of light-shading blocks 151 arranged at intervals.

Please refer to FIG. 5, FIG. 5 is a schematic structural diagram of step 15 of the manufacturing method.

Specifically, the metal layer 150 is patterned by a yellow light process, and a sectional shape of each of the light-shading blocks 151 can be a square, a trapezoid, or a cone. Different shapes can be adjusted according to a process accuracy. Spacings between the light-shading blocks 151 can also be different, which is not limited by the embodiments of the present application. The light-shading blocks 151 are made of titanium alloy, titanium molybdenum alloy, or ferroalloy. A thickness of the light-shading blocks 151 is less than 3000 angstroms.

The light-shading blocks 151 can replace the light-shading layer 180 in the prior art. Therefore, a step of preparing the light-shading layer 180 can be canceled, and cost of the light-shading layer 180 can be saved. Furthermore, there is no need to prepare buffer holes 190, which saves a mask for preparing the buffer holes 190 and further saves cost.

Step 16: preparing a second substrate layer 160 on the metal layer 150, and the second substrate layer 160 covering the light-shading blocks 151.

Please refer to FIG. 6, FIG. 6 is a schematic structural diagram of step 16 of the manufacturing method.

Specifically, the second substrate layer 160 is coated on the metal layer 150, and parts of the second substrate layer 160 located between the light-shading blocks 151 bulge downward to form a plurality of bumps. The light-shading blocks 151 arranged at intervals can improve the surface roughness, increase an adhesion of the first barrier layer 140 to the second substrate layer 160, and prevent the second substrate layer 160 from peeling off or cracking. The plurality of bumps formed by the downward projection of the second substrate layer can disperse bending stress and improve flexibility of the array substrate.

Step 17: preparing a second barrier layer 170 on the second substrate layer 160.

Please refer to FIG. 7, FIG. 7 is a schematic structural diagram of step 17 of the manufacturing method.

Specifically, the second barrier layer 170 is deposited on the second substrate layer 160. The second barrier layer 170 comprises a multilayer film. Specific steps comprise: preparing a first silicon oxide layer 171 on the second substrate layer 160; preparing a silicon nitride layer 172 on the first silicon oxide layer 171; and preparing a second silicon oxide layer 173 on the silicon nitride layer 172.

Step 2: preparing a thin-film transistor structure layer 20 on the substrate layer 10.

Specifically, the step 2 comprises steps 21 to 24.

Step 21: preparing a buffer layer 210 on the substrate layer 10.

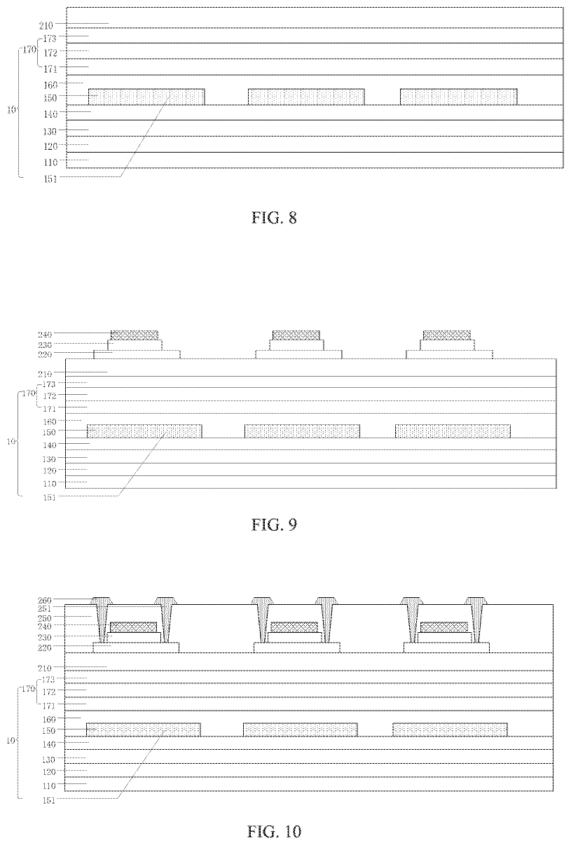

Please refer to FIG. 8, FIG. 8 is a schematic structural diagram of step 21 of the manufacturing method.

Specifically, the buffer layer 210 is deposited on the second barrier layer 170. A material of the buffer layer 210 is silicon nitride, silicon oxide, or silicon oxynitride. A thickness of the buffer layer 210 ranges from 1000 angstroms and 5000 angstroms.

The buffer layer 210 is used to block water and oxygen on the shading layer 180. In the embodiment, the second barrier layer 170 has been made of a material that blocks water and oxygen, so the buffer layer 210 can be omitted, thereby saving costs, and simplifying the manufacturing process.

Step 22: preparing an active layer 220 on the buffer layer 210, preparing a gate insulating layer 230 on the active layer 220, and preparing a gate electrode layer 240 on the gate insulating layer 230.

Please refer to FIG. 9, FIG. 9 is a schematic structural diagram of step 22 of the manufacturing method.

Specifically, the active layer 220 is deposited on the buffer layer 210. A material of the active layer 220 can be any one of indium gallium zinc oxide (IGZO), indium zinc tin oxide (IZTO), indium gallium zinc tin oxide (IGZTO), indium tin oxide (ITO), indium zinc oxide (IZO), indium aluminum zinc oxide (IAZO), indium gallium tin oxide (IGTO), or antimony tin oxide (ATO). The above materials have good conductivity and transparency, and thicknesses are small, which will not affect an overall thickness of a display panel. At a same time, it can also reduce harmful electronic radiation and ultraviolet and infrared light. A thickness of the active layer 220 ranges from 100 angstroms to 1000 angstroms.

The gate insulating layer 230 is deposited on the active layer 220. A material of the gate insulating layer 230 is an inorganic layer of silicon oxide or silicon nitride, and the gate insulating layer 230 can comprise a single layer or multiple layers. A thickness of the gate insulating layer 230 ranges from 1000 angstroms and 3000 angstroms.

The gate electrode layer 240 is deposited on the gate insulating layer 230. The gate electrode layer 240 can be a single layer of molybdenum, a single layer of aluminum, a single layer of copper, or a single layer of titanium, or a stack of molybdenum/aluminum/molybdenum, an aluminum/molybdenum stack, an aluminum/copper stack, or a stack of molybdenum titanium alloy/copper. A thickness of the gate electrode layer 240 ranges from 500 angstroms to 10000 angstroms.

A part above the active layer 220 not covered by the gate insulating layer 230 is treated with plasma to form an N+conductor area for subsequent connections with source/drain electrodes. A part covered by the gate insulating layer 230 is not treated and is used as channels of the thin-film transistor devices.

Step 23: preparing an interlayer dielectric layer 250 on the gate electrode layer 240, preparing contact holes 251, and preparing a source/drain electrode layer 260 on the interlayer dielectric layer 250.

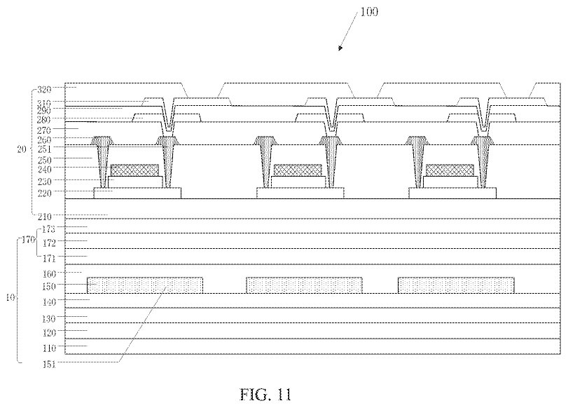

Please refer to FIG. 10, FIG. 10 is a schematic structural diagram of step 23 of the manufacturing method. Specifically, the interlayer dielectric layer 250 is deposited on the gate electrode layer 240 as a dielectric layer, and the interlayer dielectric layer 250 can comprise an inorganic material or an organic material. The inorganic material can comprise at least one selected from silicon nitride, aluminum nitride, zirconium nitride, titanium nitride, hafnium nitride, tantalum nitride, silicon oxide, aluminum oxide, titanium oxide, tin oxide, cerium oxide, and silicon oxynitride. The organic material can comprise at least one selected from acrylic resin, methacrylic resin, polyisoprene, vinyl resin, epoxy resin, urethane resin, cellulose resin, and perylene resin. A thickness of the deposited interlayer insulation layer ranges from 3000 angstroms to 10000 angstroms.

A material of the source/drain electrode 260 can be any one or more of silver, molybdenum, aluminum, or copper. A thickness of the source/drain electrode 260 ranges from 2000 angstroms to 10000 angstroms.

The contact holes 251 extends from a side of the interlayer dielectric layer 250 away from the substrate layer 10 to a surface of the active layer 220 away from the substrate layer 10, and the source/drain electrode 260 is connected to the active layer 220 through the contact holes 251 to form the thin-film transistor devices. The light-shading blocks 151 are arranged corresponding to the thin-film transistor devices, and projections of the thin-film transistor devices on the first substrate layer 130 falls within projections of the light-shading blocks 151 on the first substrate layer 130. The light-shading block 151 are used to shield the thin-film transistor devices from ambient light from a bottom of the array substrate for.

Step 24: preparing a passivation layer 270 on the source/drain electrode layer 260, preparing a wiring layer 280 on the passivation layer 270, preparing a planarization layer 290 on the wiring layer 280, preparing a pixel electrode layer 310 on the planarization layer 290, and preparing a pixel definition layer 320 on the pixel electrode layer 310.

Please refer to FIG. 11, FIG. 11 is a schematic structural diagram of step 24 of the manufacturing method.

Specifically, the passivation layer 270 is deposited on the source/drain electrode 260. A material of the passivation layer 270 is silicon oxide; and a thickness of the passivation layer 270 ranges from 1000 angstroms to 5000 angstroms.

A thickness of the wiring layer 280 ranges from 500 angstroms to 1000 angstroms.

The planarization layer 290 can comprise organic materials such as acrylic, polyimide (PI) or benzocyclobutene (BCB), and the planarization layer 290 has a planarizing effect. A thickness of the planarization layer 290 ranges from 1000 angstroms to 40000 angstroms.

The pixel electrode layer 310 is deposited on the planarization layer 290, and the pixel electrode layer 310 adopts a stack of highly reflective metal materials, such as ITO/silver (Ag)/ITO, IZO/Ag/IZO, ITO/aluminum (Al)/ITO, or IZO/Al/IZO. The pixel electrode layer 310 is also connected with the source/drain electrode layer 260.

The pixel definition layer 320 can be a photoresist layer of different components. A thickness of the pixel definition layer 320 ranges from 10000 angstroms to 20000 angstroms.

The embodiments of the present application give an exemplary description of the manufacturing of the array substrate 100. It is understandable that the array substrate 100 can further comprise other devices. Other devices and their assemblies are technical means well known to those skilled in the art and will not be repeated here.

The array substrate and the manufacturing method thereof provided in the present invention is described in detail above. And in this paper, specific examples are applied to explain the principle and implementation mode of the application. The above embodiments are only examples of the implementation of the present invention. It must be noted that the disclosed embodiments do not limit the scope of the present invention. On the contrary, the modification and equalization of the spirit and scope comprised in the claims are comprised in the scope of the invention.

What is claimed is:

1. An array substrate, comprising a substrate layer, and a thin-film transistor structure layer disposed on the substrate layer; the substrate layer comprising:
a first substrate layer;
a first barrier layer disposed on the first substrate layer;
a metal layer disposed on the first barrier layer, and the metal layer comprising a plurality of light-shading blocks arranged at intervals; and
a second substrate layer disposed on the metal layer and covering the plurality of light-shading blocks arranged at intervals.

2. The array substrate according to claim 1, wherein parts of the second substrate layer located between the light-shading blocks form a plurality of bumps facing the first substrate layer.

3. The array substrate according to claim 2, wherein the thin-film transistor structure layer comprises a plurality of thin-film transistor devices, the light-shading blocks are arranged corresponding to the thin-film transistor devices one-to-one, and projections of the thin-film transistor devices on the first substrate fall within projections of the light-shading blocks on the first substrate layer.

4. The array substrate according to claim 1, wherein a sectional shape of each of the light-shading blocks is a square, a trapezoid, or a cone. The array substrate according to claim 1, wherein a material of the light-shading blocks comprises titanium alloy, titanium molybdenum alloy, or ferroalloy, and a thickness of the light-shading blocks is greater than 0 angstrom and less than 3000 angstroms.

6. The array substrate according to claim 2, wherein the first barrier layer is an inorganic insulating layer, the plurality of light-shading blocks arranged at intervals are disposed on the inorganic insulating layer, and the plurality of bumps are in contact with the inorganic insulating layer.

7. The array substrate according to claim 1, wherein the substrate layer further comprises:
a base; and
a first isolation layer disposed on the base;
wherein the first substrate layer is disposed on the first isolation layer.

8. The array substrate according to claim 7, wherein the substrate layer further comprises a second barrier layer arranged on the second substrate layer; wherein the second barrier layer comprises:
a first silicon oxide layer disposed on the second substrate layer;
a silicon nitride layer disposed on the first silicon oxide layer;
a second silicon oxide layer disposed on the silicon nitride layer;
wherein the thin-film transistor structure layer is disposed on the second silicon oxide layer.

9. The array substrate according to claim 3, wherein the thin-film transistor structure layer further comprises:
an active layer disposed on the substrate layer;
a gate insulating layer disposed on the active layer;
a gate electrode layer disposed on the gate insulating layer;
an interlayer dielectric layer disposed on the gate electrode layer; wherein the interlayer dielectric layer is defined with contact holes, the contact holes extend from a side of the interlayer dielectric layer away from the substrate layer to a surface of the active layer away from the substrate layer;
a source/drain electrode layer disposed on the interlayer dielectric layer, wherein the source/drain electrode layer is connected to the active layer through the contact holes to form the thin-film transistor devices.

10. An array substrate, comprising a substrate layer, and a thin-film transistor structure layer disposed on the substrate layer; the substrate layer comprising:
a first substrate layer;
a first barrier layer disposed on the first substrate layer;
a metal layer disposed on the first barrier layer, the metal layer comprising a plurality of light-shading blocks arranged at intervals, and a thickness of the light-shading blocks being greater than 0 angstrom and less than 3000 angstroms; and
a second substrate layer disposed on the metal layer and covering the plurality of light-shading blocks arranged at intervals, and parts of the second substrate layer located between the light-shading blocks forming a plurality of bumps facing the first substrate layer.

11. The array substrate according to claim 10, wherein the thin-film transistor structure layer comprises a plurality of thin-film transistor devices, the light-shading blocks are arranged corresponding to the thin-film transistor devices one-to-one, and projections of the thin-film transistor devices on the first substrate fall within projections of the light-shading blocks on the first substrate layer.

12. The array substrate according to claim 10, wherein a sectional shape of each of the light-shading blocks is a square, a trapezoid, or a cone.

13. The array substrate according to claim 10, wherein a material of the light-shading blocks comprises titanium alloy, titanium molybdenum alloy, or ferroalloy.

14. The array substrate according to claim 10, wherein the first barrier layer is an inorganic insulating layer, the plurality of light-shading blocks arranged at intervals are disposed on the inorganic insulating layer, and the plurality of bumps are in contact with the inorganic insulating layer.

15. The array substrate according to claim 10, wherein the substrate layer further comprises:
a base; and
a first isolation layer disposed on the base;
wherein the first substrate layer is disposed on the first isolation layer.

16. The array substrate according to claim 15, wherein the substrate layer further comprises a second barrier layer arranged on the second substrate layer; wherein the second barrier layer comprises:
a first silicon oxide layer disposed on the second substrate layer;
a silicon nitride layer disposed on the first silicon oxide layer;
a second silicon oxide layer disposed on the silicon nitride layer;
wherein the thin-film transistor structure layer is disposed on the second silicon oxide layer.

17. The array substrate according to claim 11, wherein the thin-film transistor structure layer further comprises:
an active layer disposed on the substrate layer;
a gate insulating layer disposed on the active layer;
a gate electrode layer disposed on the gate insulating layer;
an interlayer dielectric layer disposed on the gate electrode layer; wherein the interlayer dielectric layer is defined with contact holes, the contact holes extending from a side of the interlayer dielectric layer away from the substrate layer to a surface of the active layer away from the substrate layer;
a source/drain electrode layer disposed on the interlayer dielectric layer, wherein the source/drain electrode layer is connected to the active layer through the contact holes to form the thin-film transistor devices.

18. A manufacturing method for preparing the array substrate according to claim 1, wherein the manufacturing method comprises following steps:
preparing the substrate layer; and
preparing the thin-film transistor structure layer on the substrate layer;
a step of preparing the substrate layer comprises following steps:
preparing the first substrate layer;
preparing the first barrier layer on the first substrate layer;
preparing the metal layer on the first barrier layer, patterning the metal layer to form a plurality of light-shading blocks arranged at intervals; and
preparing the second substrate layer on the metal layer, and the second substrate layer covering the plurality of light-shading blocks arranged at intervals.
